(19) United States
(12) Patent Application Publication
(10) Pub. No.: US 2020/0105712 A1
(43) Pub. Date: Apr. 2, 2020

(54) METHOD AND DEVICE FOR COMPRESSION BONDING CHIP TO SUBSTRATE

(71) Applicant: CHIPBOND TECHNOLOGY CORPORATION, Hsinchu (TW)

(72) Inventors: Chin-Tang Hsieh, Kaohsiung City (TW); Chia-Jung Tu, Hsinchu City (TW)

(21) Appl. No.: 16/260,524

(22) Filed: Jan. 29, 2019

(30) Foreign Application Priority Data
Sep. 27, 2018 (TW) 107134150

(51) Int. Cl. H01L 23/00

(52) U.S. Cl. CPC H01L 24/83; H01L 24/09; H01L 24/33

(57) ABSTRACT

Method and device for compression bonding are disclosed. During compression bonding a chip to a substrate, an anti-adhesion layer on a stage is provided to contact with a solder resist layer on the substrate. The solder resist layer will not stick to the anti-adhesion layer such that the reduction of bonding precision due to the solder resist layer remains residues on the compression bonding device is preventable.

### FIELD OF THE INVENTION

This invention relates to method and device for compression bonding a chip to a substrate, in particular, residues of a solder resist layer of a substrate, which are generated from compression bonding process, is preventable.

### BACKGROUND OF THE INVENTION

In the flip-chip bonding process often used in the semiconductor package, a chip is bonded to a substrate for connecting electrodes on the chip and conductive pads on the substrate.

Performance optimization of chips and circuit layers disposed on both sides of substrate are required for meeting the demands of electronics, such as light weight, thin and rapid operating speed.

With reference to FIG. 1, a chip 10 is bonded to a substrate 20 placed on a stage 30 via a common flip-chip bonding process. A first solder resist layer 21 and a second solder resist layer 22 are disposed on different sides of the substrate 20, respectively, and the first solder resist layer 21 touches the stage 30 during bonding. With reference to FIG. 2, the first solder resist layer 21 may remain residues 21a on the stage 30 to reduce the flatness of the stage 30 during bonding such that the next chip 10 may not be electrically connected to the substrate 20 result from the alignment shift of electrodes (not shown) on the chip 10 with respect to conductive pads (not shown) on the substrate 20. Otherwise, the residues 21a on the stage 30 also may stick to the first solder resist 21 to contaminate the next substrate 20 during the next bonding cycle.

### SUMMARY

The object of the present invention is to supply an anti-adhesion layer on a stage to contact with a solder resist layer of a substrate during bonding so that the solder resist layer will not remain residues on the stage.

A method for compression bonding chip on substrate of the present invention includes the steps of: providing a substrate including a main body, a first circuit layer, a second circuit layer, a first solder resist layer and a second solder resist layer, the first circuit layer is formed on a first surface of the main body and covered by the first solder resist layer, the second circuit layer is formed on a second surface of the main body and covered by the second solder resist layer, and a plurality of conductive pads of the second circuit layer are exposed by the second solder resist layer, wherein at least one predetermined region for compression bonding is defined on the substrate; providing a chip including a plurality of electrodes; providing a compression bonding device including a stage and an anti-adhesion layer formed on the stage; and performing a compression bonding process, the at least one predetermined region of the substrate is moved to the stage such that an exposed surface of the first solder resist layer is directed toward the anti-adhesion layer and the conductive pads of the second circuit layer are located over the anti-adhesion layer, and the chip is bonded to the substrate such that the electrodes are connected to the conductive pads and the chip and the substrate are bonded together, wherein the substrate is supported on the anti-adhesion layer and contacts with the anti-adhesion layer from the first solder resist layer during the compression bonding process.

A device for compression bonding chop on substrate of the present invention includes a stage and an anti-adhesion layer formed on the stage. The anti-adhesion layer is provided to support a substrate and contact with a solder resist layer of the substrate during a compression bonding process for bonding a chip to the substrate.

In the present invention, the anti-adhesion layer on the stage is provided to contact with the first solder resist layer of the substrate to prevent the first solder layer from remaining the residues on the stage.

### DESCRIPTION OF THE DRAWINGS

FIG. 1 is a diagram illustrating a conventional flip-chip bonding process.

FIG. 2 is a diagram illustrating a conventional stage for bonding process.

FIG. 3 is a flow chart illustrating a compression bonding method in accordance with one embodiment of the present invention.

FIG. 4A is a diagram illustrating a substrate provided in the compression bonding method in accordance with one embodiment of the present invention.

FIG. 4B is a diagram illustrating a chip provided in the compression bonding method in accordance with one embodiment of the present invention.

FIG. 4C is a diagram illustrating a compression bonding device provided in the compression bonding method in accordance with one embodiment of the present invention.

FIG. 4D is a diagram illustrating a compression bonding process in accordance with one embodiment of the present invention.

FIG. 5A is a diagram illustrating a compression bonding process in accordance with one embodiment of the present invention.

FIG. 5B is a top view diagram illustrating an anti-adhesion layer in accordance with one embodiment of the present invention.

FIG. 6A is a diagram illustrating a compression bonding process in accordance with one embodiment of the present invention.

FIG. 6B is a top view diagram illustrating an anti-adhesion layer in accordance with one embodiment of the present invention.

FIG. 7A is a diagram illustrating a compression bonding process in accordance with one embodiment of the present invention.

FIG. 7B is a top view diagram illustrating an anti-adhesion layer in accordance with one embodiment of the present invention.

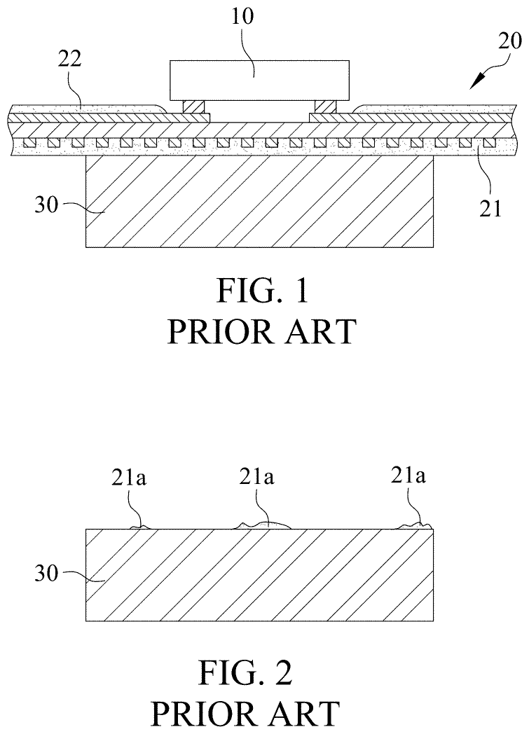

### DETAILED DESCRIPTION OF THE INVENTION

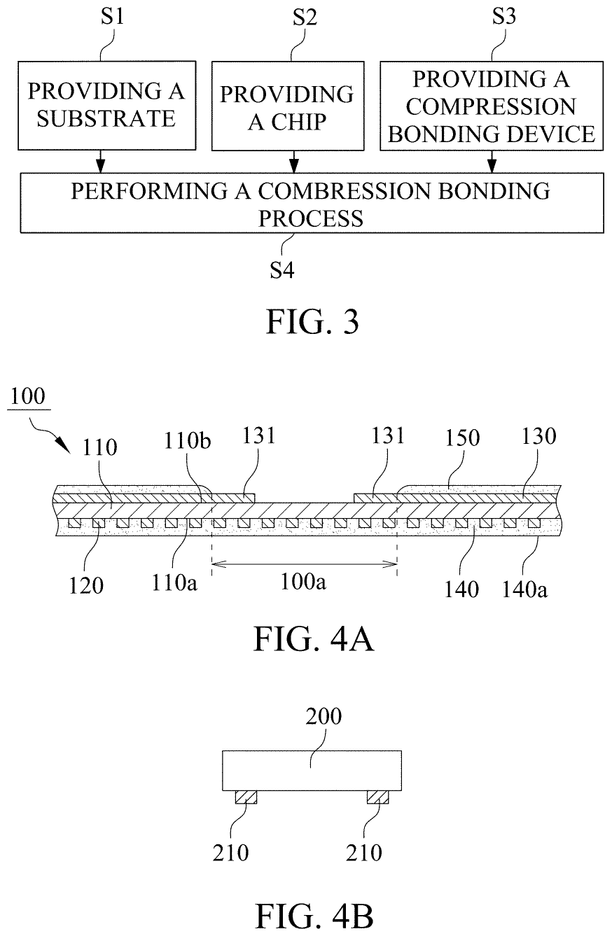

With reference to FIG. 3, a method for compression bonding chip to substrate of one embodiment of the present invention includes step S1 of providing a substrate, step S2 of providing a chip, step S3 of providing a compression bonding device and step S4 of performing a compression bonding process.

With reference to FIG. 3, the sequence of the steps S1, S2 and S3 in the present invention is not limited to the order described previously.

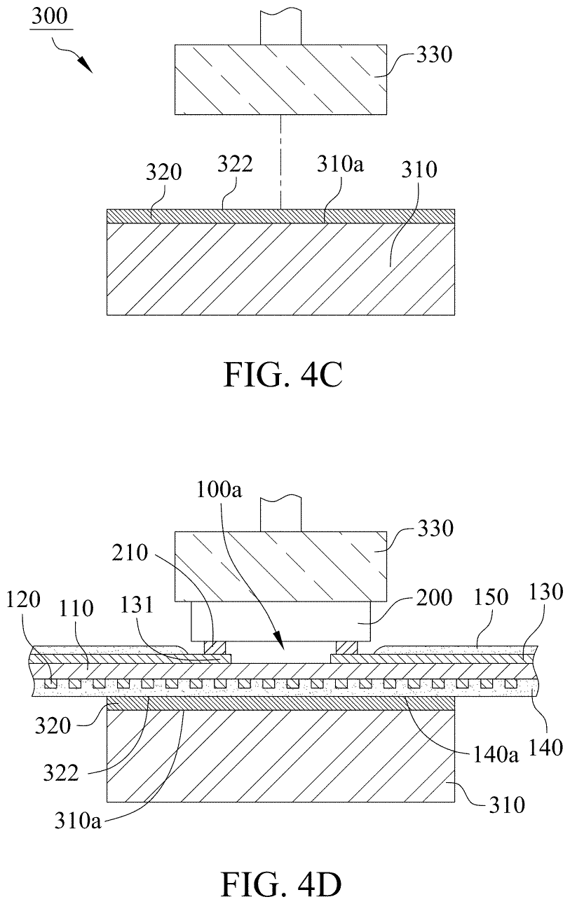

With reference to FIGS. 3 and 4A, a substrate 100 provided in the step S1 is, but not limit to, a tape carrier. A plurality of predetermined regions 100a for compression bonding are defined on the substrate 100. The substrate 100 includes a main body 110, a first circuit layer 120, a second circuit layer 130, a first solder resist layer 140 and a second solder resist layer 150. The first circuit layer 120 is formed on a first surface 110a of the main body 110 and covered by the first solder resist layer 140. The second circuit layer 130 is formed on a second surface 110b of the main body 110 and covered by the second solder resist layer 150. A plurality of conductive pads 131 of the second circuit layer 130 are located within the predetermined regions 100a and exposed by the second solder resist layer 150.

With reference to FIGS. 3 and 4B, a chip 200 provided in the step S2 includes a plurality of electrodes 210 and is designed to be electrically connected to the substrate 100 by bonding the electrodes 210 to the conductive pads 131 located within the predetermined regions 100a.

With reference to FIGS. 3 and 4C, a compression bonding device 300 provided in the step S3 includes a stage 310, an anti-adhesion layer 320 and a compression head 330. The anti-adhesion layer 320 is formed on the stage 310, and preferably, a surface 310a of the stage 310 is roughed in advance before forming the anti-adhesion layer 320 on the stage 310 such that the anti-adhesion layer 320 can be attached onto the roughed surface 310a of the stage 310 steadily. The anti-adhesion layer 320 may be made of polytetrafluoroethylene (PTFE) and formed on the stage 310 by screen printing, spray coating, roller coating or film attachment. The anti-adhesion layer 320 may be formed as a thin film in advance and is stuck on the compression head 330 before pasting on the stage 310.

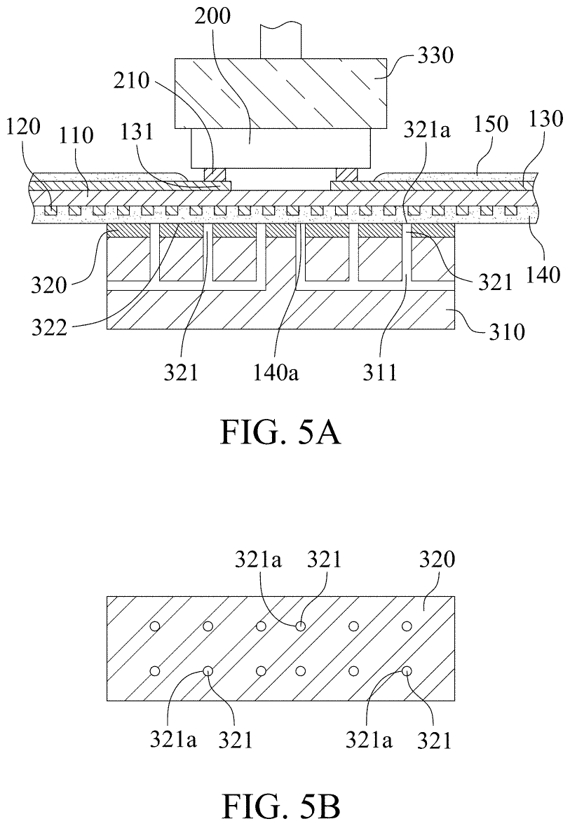

FIGS. 5A and 5B show the compression bonding device 300 of another embodiment. There are a plurality of first channels 321 and second channels 311 for air flow on the anti-adhesion layer 320 and the stage 310, respectively. The second channels 311 communicate with the first channels 321. The first channels 321 each have an opening 321a located on a supporting surface 322 of the anti-adhesion layer 320.

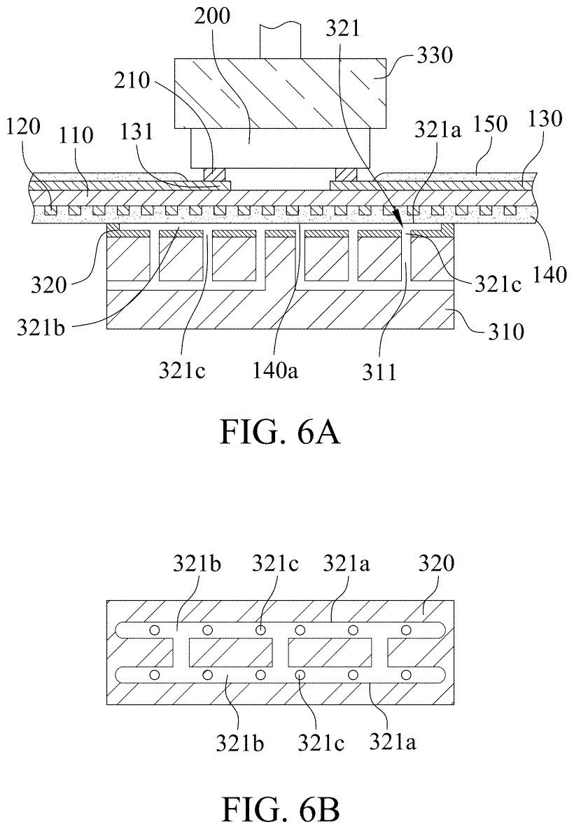

With reference to FIGS. 6A and 6B, in an embodiment different to that shown in FIGS. 5A and 5B, there are a plurality of grooves 321b in the first channels 321 and the openings 321a are the openings of the grooves 321b. Preferably, the grooves 321b are connected with each other to partition the anti-adhesion layer 320 into multiple blocks and ends of the grooves 321b are closed. Referring to FIG. 6A, the anti-adhesion layer 320 is not pierced by the grooves 321b, and there are a plurality of via holes 321c in the first channels 321, which communicate with the grooves 321b.

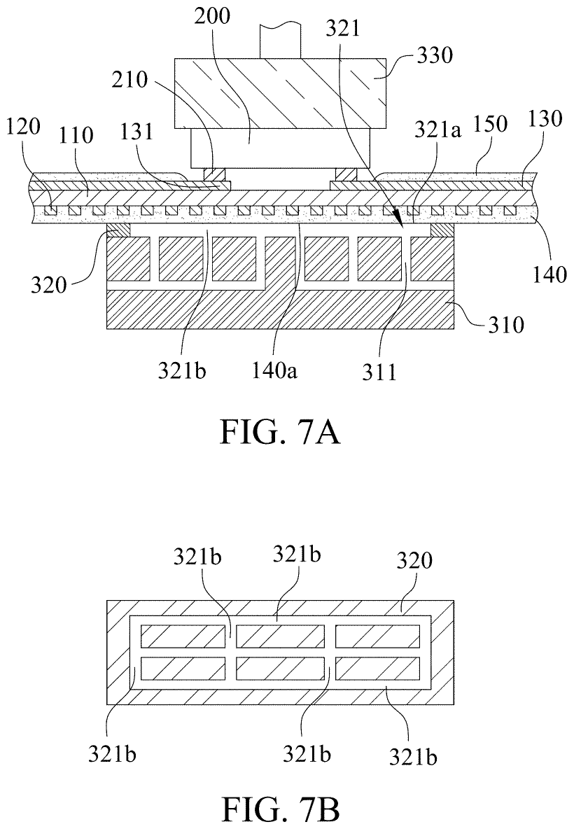

With reference to FIGS. 7A and 7B, in an embodiment different to that shown in FIGS. 6A and 6B, the anti-adhesion layer 320 is pierced by the grooves 321b, and preferably, the grooves 321b are connected to one another to divide the anti-adhesion layer 320 into multiple blocks.

With reference to FIGS. 3 and 4D, the compression bonding process of the step S4 may be performed at a temperature higher than the room temperature. Firstly, the at least one predetermined region 100a of the substrate 100 is moved to the stage 310 such that an exposed surface 140a of the first solder resist layer 140 is directed toward the supporting surface 322 of the anti-adhesion layer 320 and the conductive pads 131 of the second circuit layer 130 are located over the anti-adhesion layer 320. Next, the chip 200 and the substrate 100 are pressed toward the stage 310 by the compression head 330 to allow the first solder resist layer 140 to contact with the anti-adhesion layer 320 and allow the electrodes 210 to bond with the conductive pads 131 such that the chip 200 and the substrate 100 are bonded together. During the compression bonding process, the substrate 100 is supported on the anti-adhesion layer 320 and contacts with the anti-adhesion layer 320 from the first solder resist layer 140.

In the compression bonding process of the different embodiment as shown in FIGS. 5A, 6A and 7A, the substrate 100 is sucked via the openings 321a of the first channels 321 to be held on the anti-adhesion layer 320 temporarily. For this reason, the shift between the electrodes 210 on the chip 200 and the conductive pads 131 on the substrate 100 caused by the displacement of the substrate 100 is avoidable during connecting the electrodes 210 to the conductive pads 131.

The substrate 100 is moved away from the stage 310 to separate the first solder resist layer 140 and the anti-adhesion layer 320 after bonding. Referring to FIGS. 5A, 6A and 7A, an air is preferably supplied through the first channels 321, the second channels 311 and the openings 321a to move the substrate 100 away from the anti-adhesion layer 320.

In the present invention, the anti-adhesion layer 320 on the stage 310 is provided to contact with the first solder resist layer 140 of the substrate 100 in order to prevent the first solder resist layer 140 from remaining residues on the stage 310 during the compression bonding process. Consequently, the supporting surface 322 of the anti-adhesion layer 320 without residues has a sufficient flatness for the next compression bonding process and the contamination of the substrate 100 result from residues of the first solder resist layer 140 is preventable.

While this invention has been particularly illustrated and described in detail with respect to the preferred embodiments thereof, it will be clearly understood by those skilled in the art that is not limited to the specific features shown and described and various modified and changed in form and details may be made without departing from the spirit and scope of this invention.

What is claimed is:

1. A compression bonding method, comprising:
providing a substrate and a chip, the substrate includes a main body, a first circuit layer, a second circuit layer, a first solder resist layer and a second solder resist layer, the first circuit layer is formed on a first surface of the main body and covered by the first solder resist layer, the second circuit layer is formed on a second surface of the main body and covered by the second solder resist layer, a plurality of conductive pads of the second circuit layer are exposed by the second solder resist layer, the chip includes a plurality of electrodes, wherein at least one predetermined region for compression bonding is defined on the substrate;
providing a compression bonding device including a stage and an anti-adhesion layer formed on the stage; and
performing a compression bonding process, the at least one predetermined region of the substrate is moved to the stage such that an exposed surface of the first solder resist layer is directed toward the anti-adhesion layer and the conductive pads of the second circuit layer are located over the anti-adhesion layer, and the chip is bonded to the substrate such that the electrodes are connected to the conductive pads and the chip and the substrate are bonded together, wherein the substrate is supported on the anti-adhesion layer and contacts with the anti-adhesion layer from the first solder resist layer during the compression bonding process.

2. The compression bonding method in accordance with claim 1, wherein the anti-adhesion layer is made of polytetrafluoroethylene (PTFE).

3. The compression bonding method in accordance with claim 1, wherein there are a plurality of first channels on the anti-adhesion layer, and a plurality of openings of the first channels are located on a supporting surface of the anti-adhesion layer, the supporting surface is directed toward the first solder resist layer, wherein the substrate is sucked via the openings to be held on the anti-adhesion layer temporarily such that the first solder resist layer contacts with the anti-adhesion layer.

4. The compression bonding method in accordance with claim 3, wherein the first channels include a plurality of grooves, and the openings of the first channels are openings of the grooves.

5. The compression bonding method in accordance with claim 4, wherein the anti-adhesion layer is not pierced by the grooves whose ends are closed, and the first channels include a plurality of via holes communicating with the grooves.

6. The compression bonding method in accordance with claim 4, wherein the anti-adhesion layer is pierced by the grooves.

7. The compression bonding method in accordance with claim 4, wherein the grooves are connected with each other to partition the anti-adhesion layer into a plurality of blocks.

8. The compression bonding method in accordance with claim 3, wherein there are a plurality of second channels on the stage, and the second channels communicate with the first channels.

9. The compression bonding method in accordance with claim 1, wherein a surface of the stage is roughed in advance before forming the anti-adhesion layer on the stage such that the anti-adhesion layer is able to be attached on the roughed surface of the stage steadily.

10. The compression bonding method in accordance with claim 1, wherein the anti-adhesion layer is formed on the stage by screen printing, spray coating, roller coating or film attachment.

11. A compression bonding device, comprising:
a stage; and
an anti-adhesion layer formed on the stage, the anti-adhesion layer is provided to support a substrate and contact with a solder resist layer of the substrate during a compression bonding process for bonding a chip to the substrate.

12. The compression bonding device in accordance with claim 11, wherein the anti-adhesion layer is made of polytetrafluoroethylene (PTFE).

13. The compression bonding device in accordance with claim 11, wherein there are a plurality of first channels on the anti-adhesion layer, and a plurality of openings of the first channels are located on a supporting surface of the anti-adhesion layer, the supporting surface is directed toward the first solder resist layer, wherein the substrate is sucked via the openings to be held on the anti-adhesion layer temporarily such that the first solder resist layer contacts with the anti-adhesion layer.

14. The compression bonding device in accordance with claim 13, wherein the first channels include a plurality of grooves, and the openings of the first channels are openings of the grooves.

15. The compression bonding device in accordance with claim 14, wherein the anti-adhesion layer is not pierced by the grooves whose ends are closed, and the first channels include a plurality of via holes communicating with the grooves.

16. The compression bonding device in accordance with claim 14, wherein the anti-adhesion layer is pierced by the grooves.

17. The compression bonding device in accordance with claim 14, wherein the grooves are connected with each other to partition the anti-adhesion layer into a plurality of blocks.

18. The compression bonding device in accordance with claim 13, wherein there are a plurality of second channels on the stage, and each of the second channels communicates with one of the first channels.

19. The compression bonding device in accordance with claim 11, wherein a surface of the stage is roughed in advance before forming the anti-adhesion layer on the stage such that the anti-adhesion layer is able to be attached on the roughed surface of the stage steadily.

20. The compression bonding device in accordance with claim 11, wherein the anti-adhesion layer is formed on the stage by screen printing, spray coating, roller coating or film attachment.
